(19) United States
(12) Patent Application Publication
(10) Pub. No.: US 2017/0005288 A1
(43) Pub. Date: Jan. 5, 2017

(54) DISPLAY DEVICES

(71) Applicant: SOLVAY SPECIALTY POLYMERS ITALY S.P.A., Bollate (IT)

(72) Inventors: Paula COJOCARU, Legnano (IT); Marco APOSTOLO, Senago (IT); Francesco Maria TRIULZI, Garbagnate Milanese (IT); Marco Alberto SPREAFICO, Rho (IT); Andrea Vittorio ORIANI, Bresso (IT)

(21) Appl. No.: 15/106,972

(22) PCT Filed: Dec. 23, 2014
(86) PCT No.: PCT/EP2014/079126

§ 371 Date: Jun. 21, 2016

(30) Foreign Application Priority Data
Dec. 23, 2013 (EP) 13199419.6

(51) Int. Cl. H01L 51/52; H01L 51/00; H01L 51/56

(52) U.S. Cl. CPC H01L 51/5215; H01L 51/56; H01L 51/0023; H01L 51/5234; H01L 2251/558; H01L 2251/5338

(57) ABSTRACT

The present invention pertains to a process for the manufacture of a display device, said process comprising the following steps: (1) providing a front-sheet electrode, (2) providing a back-sheet electrode, and (3) interposing between the front-sheet electrode and the back-sheet electrode one or more layers consisting of at least one organic semiconductor material, wherein said front-sheet electrode is an assembly comprising one or more multilayer assemblies obtainable by: (i) providing at least one layer (L1) consisting of a composition [composition (C1)] comprising, preferably consisting of at least one thermoplastic polymer [polymer (T1)], said layer (L1) having two opposite surfaces; (ii) treating at least one surface of the layer (L1) with a radio-frequency glow discharge process in the presence of an etching gas medium; (iii) applying by electroless deposition a layer consisting of at least one metal compound (M1) [Layer (L2)] onto each treated surface of the layer (L1) provided in step (ii). The present invention also pertains to the display device provided by said process and to uses of said display devices in organic electronic devices.

This application claims priority to European application No. 13199419.6 filed on Dec. 23, 2013, the whole content of this application being incorporated herein by reference for all purposes.

### TECHNICAL FIELD

The present invention pertains to a display device, to a process for its manufacture and to its uses in organic electronic devices.

### BACKGROUND ART

Organic electronic devices (OEDs) typically comprise one or more layers of organic materials situated between two electrodes, the anode and the cathode, all deposited on a substrate.

Non-limitative examples of known OED constructions include organic photovoltaic devices (OPVs), organic light emitting diodes (OLEDs) and organic thin-film transistors (OTFTs) such as organic field-effect transistors (OFETs).

Since the primary application of these OED devices is in liquid crystal displays, glass is commonly used as substrate in these OED constructions. With the increasing demand for flexible electronics, there is great interest in replacing glass substrates with polymer substrates optically transparent to visible light, particularly in flat panel display technology where low volume, lightweight and robustness are important.

It is well known that organic materials may be adversely affected by oxygen and moisture which may easily penetrate into the polymer substrates.

To prevent contaminants such as oxygen and moisture from penetrating into a substrate, separate encapsulation and fabrication steps in an inert environment are typically required and manufacturing costs considerably increase.

At present, Sn-doped In₂O₃ (ITO), which is advantageously optically transparent to visible light, is the most widely employed material for the manufacture of the anode in OED devices. However, large-scale implementation of ITO is severely hampered due to scarcity, toxicity and high cost of Indium.

Also, imperfections in the surface of the anode typically decrease anode-organic film interface adhesion, increase electrical resistance, and allow for more frequent formation of non-emissive dark spots in the OED material adversely affecting lifetime of these devices. Mechanisms to decrease anode roughness for ITO/glass substrates include the use of thin films and self-assembled monolayers.

There is thus still the need in the art for OED multilayer devices suitable for manufacturing organic electronic display devices having high barrier properties from the external environment, low thickness and good optical transparency, while exhibiting good interlayer adhesion properties, and for a process allowing easy manufacture of said display devices.

### SUMMARY OF INVENTION

It has been now surprisingly found that, by using as front sheet electrode a unitary assembly comprising a thermoplastic polymer substrate layer, it is possible to provide for the organic electronic display devices of the present invention which have advantageously a thickness as low as to provide for outstanding flexibility properties while ensuring high barrier properties from the external environment and, preferably, good optical transparency over the long term.

In particular, it has been found that the display devices of the invention are endowed with low permeability to water vapour and gases, in particular oxygen.

Also, it has been found that the display devices of the invention exhibit good interlayer adhesion properties.

Further, it has been found that said display devices can be easily obtained by the process of the invention.

In a first instance, the present invention pertains to a process for the manufacture of a display device, said process comprising the following steps:

(1) providing a front-sheet electrode,

(2) providing a back-sheet electrode, and

(3) interposing between the front-sheet electrode and the back-sheet electrode one or more layers consisting of at least one organic semiconductor material,

wherein said front-sheet electrode is an assembly comprising one or more multilayer assemblies obtainable by:

(i) providing at least one layer (L1) consisting of a composition [composition (C1)] comprising, preferably consisting of, at least one thermoplastic polymer [polymer (T1)], said layer (L1) having two opposite surfaces;

(ii) treating at least one surface of the layer (L1) with a radio-frequency glow discharge process in the presence of an etching gas medium;

(iii) applying by electroless deposition a layer consisting of at least one metal compound (M1) [layer (L2)] onto each treated surface of the layer (L1) provided in step (ii).

In a second instance, the present invention pertains to a display device comprising:
a front-sheet electrode,
a back-sheet electrode, and
directly adhered to the inner surface of the front-sheet electrode and to the inner surface of the back-sheet electrode, one or more layers consisting of at least one organic semiconductor material,

wherein the front-sheet electrode is an assembly comprising one or more multilayer assemblies comprising the following layers:
at least one layer [layer (L1)] consisting of a composition [composition (C1)] comprising, preferably consisting of, at least one thermoplastic polymer [polymer (T1)], said layer (L1) layer having two opposite surfaces,

wherein at least one surface comprises one or more grafted functional groups [surface (L1-f)], and
directly adhered to the surface (L1-f) of the layer (L1), a layer consisting of at least one metal compound (M1) [layer (L2)].

The display device of the invention is advantageously obtainable by the process of the invention.

The display device of the invention preferably comprises:
a front-sheet electrode,
a back-sheet electrode, and
directly adhered to the inner surface of the front-sheet electrode and to the inner surface of the back-sheet electrode, one or more layers consisting of at least one organic semiconductor material,

wherein the front-sheet electrode is an assembly comprising one or more multilayer assemblies comprising the following layers:
an outer layer (L1), said outer layer (L1) layer having two opposite surfaces, wherein the inner surface comprises one or more grafted functional groups [surface (L1-f)],
directly adhered to the surface (L1-f) of the outer layer (L1), a layer (L2),
one or more intermediate layers (L1), said intermediate layers (L1) layer having two opposite surfaces, wherein both surfaces comprise one or more grafted functional groups [surfaces (L1-f)], and
directly adhered to each surface (L1-f) of the intermediate layers (L1), a layer (L2).

For the purpose of the present invention, the term “display device” is intended to denote an output electronic device for presentation of information in visual or tactile form wherein the input information is supplied as an electrical signal.

In a third instance, the present invention pertains to use of the display device of the invention in organic electronic devices.

Thus, the present invention pertains to use of the display device of the invention in organic photovoltaic devices (OPVs), organic light emitting diodes (OLEDs) and organic thin-film transistors (OTFTs).

For the purpose of the present invention, the term “front-sheet electrode” is intended to denote an electrode construction on the front side of the display device of the invention.

For the purpose of the present invention, the term “back-sheet electrode” is intended to denote an electrode construction on the back side of the display device of the invention.

The front-sheet electrode of the display device of the invention is advantageously optically transparent.

For the purpose of the present invention, by the term “optically transparent” it is meant that the front-sheet electrode allows incident electromagnetic radiation to pass there through without being scattered.

The front-sheet electrode of the display device of the invention is advantageously optically transparent to incident electromagnetic radiation having a wavelength of from about 100 nm to about 2500 nm, preferably of from about 400 nm to about 800 nm.

The front-sheet electrode of the display device of the invention is preferably not optically transparent to incident electromagnetic radiation having a wavelength of from about 100 nm to about 400 nm.

The front-sheet electrode of the display device of the invention has advantageously a transmittance of at least 50%, preferably of at least 55%, more preferably of at least 60% of the incident electromagnetic radiation.

The transmittance can be measured using a spectrophotometer according to any suitable techniques.

The front-sheet electrode of the display device of the invention has typically a thickness comprised between 5 μm and 150 μm, preferably of about 100 μm.

The front-sheet electrode of the display device of the invention is advantageously the anode of said display device.

The back-sheet electrode of the display device of the invention is advantageously the cathode of said display device.

The back-sheet electrode is not particularly limited. The skilled in the art, depending on the nature of the display device of the invention, will select the proper back-sheet electrode suitable for use therein.

For the purpose of the present invention, by the term “layer” it is meant a covering piece of material or a part that lies over or under another having a thickness smaller than either of its length or its width.

For the purpose of the present invention, the term “organic semiconductor material” is intended to denote a carbon-based compound having the inherent properties of semiconductor materials.

The organic semiconductor material is not particularly limited. The skilled in the art, depending on the nature of the display device of the invention, will select the proper organic semiconductor material suitable for use therein.

The organic semiconductor material is typically selected from the group consisting of polythiophene, poly(3-alkylthiophene), polythienylenevinylene, poly(para-phenylenevinylene), polyfluorenes and mixtures thereof.

For the purpose of the present invention, the term “thermoplastic polymer” is intended to denote whichever polymer existing, at room temperature, below its glass transition temperature, if it is amorphous, or below its melting point, if it is semi-crystalline, and which is linear or branched (i.e. not reticulated). The thermoplastic polymer has the property of becoming soft when it is heated and of becoming rigid again when it is cooled, without there being an appreciable chemical change. Such a definition may be found, for example, in the encyclopaedia called “Polymer Science Dictionary”, Mark S. M. Alger, London School of Polymer Technology, Polytechnic of North London, UK, published by Elsevier Applied Science, 1989.

The layer (L1) is advantageously optically transparent.

The layer (L1) of the front-sheet electrode of the display device of the invention is usually the outer layer of said display device.

The surface (L1-f) of the layer (L1) is advantageously obtainable by treating at least one surface of the layer (L1) with a radio-frequency glow discharge process in the presence of an etching gas medium.

The term “functional group” is used herein according to its usual meaning to denote a group of atoms linked to each other by covalent bonds which is responsible for the reactivity of the surface (L1-f) of the polymer (T1).

For the purpose of the present invention, the term “grafted functional groups” is intended to denote functional groups obtainable by grafting onto to the main chain of the polymer (T1).

For the purpose of the present invention, the term “grafting” is used according to its usual meaning to denote a radical process by which one or more functional groups are inserted onto the surface of a polymer backbone.

The grafted functional groups obtainable by treating at least one surface of the layer (L1) with a radio-frequency glow discharge process in the presence of an etching gas medium typically comprise at least one atom of said etching gas medium.

The layer (L1) has typically a thickness of at least 5 μm, preferably of at least 10 μm. Layers (L1) having thickness of less than 5 μm, while still suitable for the insulation system of the invention, will not be used when adequate mechanical resistance is required.

As per the upper limit of the thickness of the layer (L1), this is not particularly limited, provided that said layer (L1) still can provide the flexibility required for the particular field of use targeted.

The layer (L1) has typically a thickness of at most 50 μm, preferably of at most 30 μm.

The skilled in the art, depending on the nature of the polymer (T1), will select the proper thickness of the layer (L1) so as to provide for the permeability and flexibility properties required.

Also, the skilled in the art, depending on the nature of the polymer (T1), will select the proper thickness of the layer (L1) so as to provide for the optical transparency required.

The polymer (T1) is preferably selected from the group consisting of:
fluoropolymers comprising recurring units derived from at least one fluorinated monomer,
polyesters such as polyethylene terephthalate, polybutylene terephthalate, polyethylene naphthalate and copolymers thereof,
polyolefins such as low-density, linear low-density and high-density polyethylene, polypropylene and biaxially oriented polypropylene, and polybutylene,
substituted polyolefins such as polystyrene,
polyethersulfones,
polycarbonates,
polyacrylates, and
polyimides.

By the term “fluorinated monomer” it is hereby intended to denote an ethylenically unsaturated monomer comprising at least one fluorine atom.

The term “at least one fluorinated monomer” is understood to mean that the fluoropolymer may comprise recurring units derived from one or more than one fluorinated monomers. In the rest of the text, the expression “fluorinated monomers” is understood, for the purposes of the present invention, both in the plural and the singular, that is to say that they denote both one or more than one fluorinated monomers as defined above.

Non limitative examples of suitable fluorinated monomers include, notably, the followings:
C₃-C₈ perfluoroolefins, such as tetrafluoroethylene (TFE) and hexafluoropropene (HFP);
C₂-C₈, hydrogenated fluoroolefins, such as vinylidene fluoride (VDF), vinyl fluoride, 1,2-difluoroethylene and trifluoroethylene (TrFE);
perfluoroalkylethylenes of formula CH₂═CH—R_{f0} wherein R_{f0} is a C₁-C₆ perfluoroalkyl group;
chloro- and/or bromo- and/or iodo-C₂-C₆ fluoroolefins, such as chlorotrifluoroethylene (CTFE);
(per)fluoroalkylvinylethers of formula CF₂═CFOR_{f1} wherein R_{f1} is a C₁-C₆ fluoro- or perfluoroalkyl group, CF₃, C₂F₅, C₃F₇;
CF₂═CFOX₀ (per)fluoro-oxyalkylvinylethers, wherein X₀ is a C₁-C₁₂ alkyl group, a C₁-C₁₂ oxyalkyl group or a C₁-C₁₂ (per)fluorooxyalkyl group comprising one or more ether groups, such as perfluoro-2-propoxy-propyl group;
(per)fluoroalkylvinylethers of formula CF₂═CFOCF₂OR_{f2} wherein R_{f2} is a C₁-C₆ fluoro- or perfluoroalkyl group, e.g. CF₃, C₂F₅, C₃F₇ or a C₁-C₆ (per)fluorooxyalkyl group comprising one or more ether groups, such as —C₂F₅—O—CF₃;
functional (per)fluoro-oxyalkylvinylethers of formula CF₂═CFOY₀,

wherein Y₀ is a C₁-C₁₂ alkyl or (per)fluoroalkyl group, a C₁-C₁₂ oxyalkyl group or a C₁-C₁₂ (per)fluorooxyalkyl group comprising one or more ether groups and Y₀ comprising a carboxylic or sulfonic acid group, in its acid, acid halide or salt form;
fluorodioxoles, preferably perfluorodioxoles; and
cyclopolymerizable monomers of formula CR₇R₈═CR₉OCR₁₀R₁₁(CR₁₂R₁₃)ₐ(O)_{b}CR₁₄═CR₁₅R₁₆, wherein each R₇ to R₁₆, independently of one another, is selected from —F and a C₁-C₃ fluoroalkyl group, a is 0 or 1, b is 0 or 1 with the proviso that b is 0 when a is 1.

The fluoropolymer may further comprise at least one hydrogenated monomer.

By the term “hydrogenated monomer” it is hereby intended to denote an ethylenically unsaturated monomer comprising at least one hydrogen atom and free from fluorine atoms.

The term “at least one hydrogenated monomer” is understood to mean that the fluoropolymer may comprise recurring units derived from one or more than one hydrogenated monomers. In the rest of the text, the expression “hydrogenated monomers” is understood, for the purposes of the present invention, both in the plural and the singular, that is to say that they denote both one or more than one hydrogenated monomers as defined above.

Non limitative examples of suitable hydrogenated monomers include, notably, non-fluorinated monomers such as ethylene, propylene, vinyl monomers such as vinyl acetate, (meth)acrylic monomers and styrene monomers such as styrene and p-methylstyrene.

The fluoropolymer may be semi-crystalline or amorphous.

The term “semi-crystalline” is hereby intended to denote a fluoropolymer having a heat of fusion of from 10 to 90 J/g, preferably of from 30 to 60 J/g, more preferably of from 35 to 55 J/g, as measured according to ASTM D3418-08.

The term “amorphous” is hereby intended to denote a fluoropolymer having a heat of fusion of less than 5 J/g, preferably of less than 3 J/g, more preferably of less than 2 J/g as measured according to ASTM D-3418-08.

The fluoropolymer is preferably selected from the group consisting of: (A) fluoropolymers comprising recurring units derived from at least one fluorinated monomer selected from tetrafluoroethylene (TFE) and chlorotrifluoroethylene (CTFE), and from at least one hydrogenated monomer selected from ethylene, propylene and isobutylene, optionally containing one or more additional comonomers, typically in amounts of from 0.01% to 30% by moles, based on the total amount of TFE and/or CTFE and said hydrogenated monomer(s); and

(B) fluoropolymers consisting of recurring units derived from chlorotrifluoroethylene (CTFE).

The fluoropolymer (A) as defined above preferably comprises recurring units derived from ethylene (E) and at least one of chlorotrifluoroethylene (CTFE) and tetrafluoroethylene (TFE).

The fluoropolymer (A) as defined above more preferably comprises:

(a) from 30% to 48%, preferably from 35% to 45% by moles of ethylene (E);

(b) from 52% to 70%, preferably from 55% to 65% by moles of chlorotrifluoroethylene (CTFE), tetrafluoroethylene (TFE) or mixture thereof; and

(c) up to 5%, preferably up to 2.5% by moles, based on the total amount of monomers (a) and (b), of one or more fluorinated and/or hydrogenated comonomer(s).

The comonomer is preferably a hydrogenated comonomer selected from the group of the (meth)acrylic monomers. The hydrogenated comonomer is more preferably selected from the group of the hydroxyalkylacrylate comonomers, such as hydroxyethylacrylate, hydroxypropylacrylate and (hydroxy)ethylhexylacrylate, and alkyl acrylate comonomers, such as n-butyl acrylate.

Among fluoropolymers (A) as defined above, ECTFE copolymers, i.e.

copolymers of ethylene and CTFE and, optionally, a third comonomer are preferred.

ECTFE polymers suitable in the process of the invention typically possess a melting temperature not exceeding 210° C., preferably not exceeding 200° C., even not exceeding 198° C., preferably not exceeding 195° C., more preferably not exceeding 193° C., even more preferably not exceeding 190° C. The ECTFE polymer has a melting temperature of advantageously at least 120° C., preferably of at least 130° C., still preferably of at least 140° C., more preferably of at least 145° C., even more preferably of at least 150° C.

The melting temperature is determined by Differential Scanning Calorimetry (DSC) at a heating rate of 10° C./min, according to ASTM D 3418.

ECTFE polymers which have been found to give particularly good results are those consisting essentially of recurring units derived from:

(a) from 35% to 47% by moles of ethylene (E);

(b) from 53% to 65% by moles of chlorotrifluoroethylene (CTFE).

End chains, defects or minor amounts of monomer impurities leading to recurring units different from those above mentioned can be still comprised in the preferred ECTFE, without this affecting properties of the material.

The melt flow rate of the ECTFE polymer, measured following the procedure of ASTM 3275-81 at 230° C. and 2.16 Kg, ranges generally from 0.01 to 75 g/10 min, preferably from 0.1 to 50 g/10 min, more preferably from 0.5 to 30 g/10 min.

The heat of fusion of the fluoropolymer (A) as defined above is determined by Differential Scanning calorimetry (DSC) at a heating rate of 10° C./min, according to ASTM D 3418.

The fluoropolymer (A) as defined above typically has a heat of fusion of at most 35 J/g, preferably of at most 30 J/g, more preferably of at most 25 J/g.

The fluoropolymer (A) as defined above typically has a heat of fusion of at least 1 J/g, preferably of at least 2 J/g, more preferably of at least 5 J/g.

The fluoropolymer (A) as defined above is advantageously a semi-crystalline polymer.

The composition (C1) may further comprise one or more additives such as, but not limited to, desiccants and oxygen scavengers. The skilled in the art, depending on the thickness of the layer (L1), will select the proper amount of one or more additives in the composition (C1).

Desiccants are typically used in the form of nanoparticles. Non-limitative examples of suitable desiccants include, notably, boron oxide, barium oxide, calcium oxide and zeolites.

The composition (C1) is typically processed in molten phase using melt-processing techniques. The composition (C1) is usually processed by extrusion through a die at temperatures generally comprised between 100° C. and 300° C. to yield strands which are usually cut for providing pellets. Twin screw extruders are preferred devices for accomplishing melt compounding of the composition (C1).

The layer (L1) is typically manufactured by processing the pellets so obtained through traditional film extrusion techniques. Film extrusion is preferably accomplished using a flat cast film extrusion process or a hot blown film extrusion process.

The layer (L1) is preferably further processed by one or more planarization techniques.

Non-limitative examples of suitable planarization techniques include, notably, bistretching, polishing and planarization coating treatments.

It has been found that by further processing the layer (L1) by one or more planarization techniques its surface is rendered smooth so as to ensure higher interlayer adhesion with the layer (L2).

By “radio-frequency glow discharge process” it is hereby intended to denote a process powered by a radio-frequency amplifier wherein a glow discharge is generated by applying a voltage between two electrodes in a cell containing an etching gas. The glow discharge so generated then typically passes through a jet head to arrive to the surface of the material to be treated.

By “etching gas medium” it is hereby intended to denote either a gas or a mixture of gases suitable for use in a radio-frequency glow discharge process.

The etching gas medium is preferably selected from the group consisting of air, N₂, NH₃, CH₄, CO₂, He, O₂, H₂ and mixtures thereof.

The etching gas medium more preferably comprises N₂ and/or NH₃ and, optionally, H₂.

The radio-frequency glow discharge process is typically carried out under reduced pressure or under atmospheric pressure.

The radio-frequency glow discharge process is preferably carried out under atmospheric pressure at about 760 Torr.

Atmospheric-pressure plasmas have prominent technical significance because, in contrast with low-pressure plasma or high-pressure plasma, no reaction vessel is needed to ensure the maintenance of a pressure level differing from atmospheric pressure.

The radio-frequency glow discharge process is typically carried out at a radio-frequency comprised between 1 kHz and 100 kHz.

The radio-frequency glow discharge process is typically carried out at a voltage comprised between 1 kV and 50 kV.

According to a first embodiment of the process of the invention, the radio-frequency glow discharge process generates a corona discharge.

The radio-frequency glow discharge process of this first embodiment of the process of the invention is typically carried out at a radio-frequency comprised between 5 kHz and 15 kHz.

The radio-frequency glow discharge process of this first embodiment of the process of the invention is typically carried out at a voltage comprised between 1 kV and 20 kV.

The corona discharge typically has a density comprised between 1×10⁹ and 1×10¹³ cm⁻³.

According to a second embodiment of the process of the invention, the radio-frequency glow discharge process generates a plasma discharge.

The radio-frequency glow discharge process of this second embodiment of the process of the invention is typically carried out at a radio-frequency comprised between 10 kHz and 100 kHz.

The radio-frequency glow discharge process of this second embodiment of the process of the invention is typically carried out at a voltage comprised between 5 kV and 15 kV.

The plasma discharge typically has a density comprised between 1×10¹⁶ and 1×10¹⁹ cm⁻³.

The Applicant has found that, after treatment of one surface of the layer

(L1) with a radio-frequency glow discharge process in the presence of an etching gas medium, the layer (L1) successfully maintains its bulk properties including its flexibility properties and its optical transparency.

Non-limitative examples of grafted functional groups of the surface (L1-f) of the layer (L1), obtainable by treatment of the surface of the layer (L1) with a radio-frequency glow discharge process in the presence of an etching gas medium comprising N₂ and/or NH₃ and, optionally, H₂, typically under atmospheric pressure, include, notably, those selected from the group consisting of amine groups (—NH₂), imine groups (—CH═NH), nitrile groups (—CN) and amide groups (—CONH₂).

The nature of the grafted functional groups of the surface (L1-f) of the layer (L1) can be determined by any suitable techniques, typically by FT-IR techniques such as Attenuated Total Reflectance (ATR) coupled to FT-IR techniques or by X-ray induced photoelectron spectroscopy (XPS) techniques.

The layer (L2) is advantageously obtainable by electroless deposition onto the surface (L1-f) of the layer (L1).

The Applicant has surprisingly found that the surface (L1-f) of the layer (L1) advantageously provides for outstanding interlayer adhesion with a layer (L2) applied thereto by electroless deposition.

The layer (L2) is advantageously optically transparent.

The metal compound (M1) is typically a metal oxide selected from the group consisting of:
SiOx, ZnO, In₂O₃, SnO₂ and mixtures thereof, wherein x is comprised between 0.5 and 2,
impurity-doped metal oxides selected from the group consisting of ZnO, In₂O₃, SnO₂, CdO and mixtures thereof such as Sn-doped metal oxides selected from the group consisting of ZnO, In₂O₃, SnO₂, CdO and mixtures thereof and Al-doped metal oxides selected from the group consisting of ZnO, In₂O₃, SnO₂, CdO and mixtures thereof, and
Zn₂SnO₄, ZnSnO₃, Zn₂In₂O₅, Zn₃In₂O₆, In₂SnO₄, CdSnO₃ and mixtures thereof.

For the purpose of the present invention, by “electroless deposition” it is meant a redox process, typically carried out in a plating bath, wherein a metal compound is reduced from its oxidation state to its elemental state in the presence of suitable chemical reducing agents.

The surface (L1-f) of the layer (L1) is typically contacted with an electroless metallization catalyst thereby providing a catalytic layer [layer (L¹_{c})].

The layer (L2) is then typically obtainable by electroless deposition onto the layer (L1_{c}) using a composition (C2) comprising at least one metal ion deriving from at least one metal compound (M1).

The Applicant thinks, without this limiting the scope of the invention, that the layer (L1_{c}) is a transient intermediate of the electroless deposition process so that the layer (L2) is finally directly adhered to the surface (L1-f) of the layer (L1).

The electroless metallization catalyst is typically selected from the group consisting of catalysts based on palladium, platinum, rhodium, iridium, nickel, copper, silver and gold.

The electroless metallization catalyst is preferably selected from palladium catalysts such as PdCl₂.

The surface (L1-f) of the layer (L1) is typically contacted with the electroless metallization catalyst in liquid phase in the presence of at least one liquid medium.

The composition (C2) typically comprises at least one metal ion deriving from at least one metal compound (M1), at least one reducing agent, at least one liquid medium and, optionally, one or more additives.

Non-(imitative examples of suitable liquid media include, notably, water, organic solvents and ionic liquids.

Among organic solvents, alcohols are preferred such as ethanol.

Non-(imitative examples of suitable reducing agents include, notably, formaldehyde, sodium hypophosphite and hydrazine.

Non-(imitative examples of suitable additives include, notably, salts, buffers and other materials suitable for enhancing stability of the catalyst in the liquid composition.

The multilayer assembly provided in step (iii) of the process of the invention is typically dried, preferably at a temperature comprised between 50° C. and 150° C., more preferably at a temperature comprised between 100° C. and 150° C.

The layer (L2) has typically a thickness comprised between 0.05 μm and 5 μm, preferably between 0.5 μm and 1.5 μm.

The thickness of the layer (L2) can be measured by any suitable techniques, typically by scanning electron microscopy (SEM) techniques.

According to a first embodiment of the invention, the front-sheet electrode of the display device of the invention is an assembly comprising one or more multilayer assemblies further comprising, directly adhered to the layer (L2), a layer consisting of at least one metal compound (M2) [layer (L3)], said metal compound (M2) being equal to or different from the metal compound (M1).

The layer (L3) is preferably obtainable by electro-deposition onto the layer (L2).

The layer (L3) is advantageously optically transparent.

For the purpose of the present invention, by “electro-deposition” it is meant a process, typically carried out in an electrolytic cell, using an electrolytic solution, wherein an electric current is used to reduce a metal compound from its oxidation state to its elemental state.

The layer (L3) is typically applied onto the layer (L2) by electro-deposition using a composition (C3) comprising at least one metal ion deriving from at least one metal compound (M2).

The metal compound (M2), equal to or different from the metal compound (M1), is typically a metal oxide selected from the group consisting of:
SiOx, ZnO, In₂O₃, SnO₂ and mixtures thereof, wherein x is comprised between 0.5 and 2,
impurity-doped metal oxides selected from the group consisting of ZnO, In₂O₃, SnO₂, CdO and mixtures thereof such as Sn-doped metal oxides selected from the group consisting of ZnO, In₂O₃, SnO₂, CdO and mixtures thereof and Al-doped metal oxides selected from the group consisting of ZnO, In₂O₃, SnO₂, CdO and mixtures thereof, and
Zn₂SnO₄, ZnSnO₃, Zn₂In₂O₅, Zn₃In₂O₆, In₂SnO₄, CdSnO₃ and mixtures thereof.

The composition (C3) preferably comprises at least one metal ion deriving from at least one metal compound (M2), at least one metal halide and, optionally, at least one ionic liquid.

Non-limitative examples of suitable ionic liquids include, notably, those comprising:
a cation selected from the group consisting of a sulfonium ion or an imidazolium, pyridinium, pyrrolidinium or piperidinium ring, said ring being optionally substituted on the nitrogen atom, in particular by one or more alkyl groups with 1 to 8 carbon atoms, and on the carbon atoms, in particular by one or more alkyl groups with 1 to 30 carbon atoms, and
an anion selected from the group consisting of halide anions, perfluorinated anions and borates.

The Applicant has also found that the layer (L2) advantageously provides for outstanding interlayer adhesion with a layer (L3) applied thereto by electro-deposition.

The multilayer assembly thereby provided is typically dried, preferably at a temperature comprised between 50° C. and 150° C., more preferably at a temperature comprised between 100° C. and 150° C.

The layer (L3), if any, has typically a thickness comprised between 0.05 μm and 5 μm, preferably between 0.5 μm and 1.5 μm.

The thickness of the layer (L3) can be measured by any suitable techniques, typically by scanning electron microscopy (SEM) techniques.

According to a second embodiment of the invention, the front-sheet electrode of the display device of the invention is an assembly comprising one or more multilayer assemblies further comprising, directly adhered to the layer (L2), a patterned layer consisting of at least one metal compound (M3) [layer (L4)], said metal compound (M3) being equal to or different from the metal compound (M1).

According to a third embodiment of the invention, the front-sheet electrode of the display device of the invention is an assembly comprising one or more multilayer assemblies further comprising:
directly adhered to the layer (L2), a layer consisting of at least one metal compound (M2) [layer (L3)], said metal compound (M2) being equal to or different from the metal compound (M1), and
directly adhered to the layer (L3), a patterned layer consisting of at least one metal compound (M3) [layer (L4)], said metal compound (M3) being equal to or different from the metal compound (M1) and the metal compound (M2).

For the purpose of the present invention, by “patterned layer” it is meant a layer having any pattern geometries.

The layer (L4) is preferably a patterned grid layer [layer (L4-g)].

For the purpose of the present invention, by “patterned grid layer” it is meant a layer having any grid pattern geometries.

The layer (L4-g) typically has a mesh size comprised between 100 μm and 800 μm, preferably between 150 μm and 500 μm.

The layer (L4-g) typically has a bar width comprised between 5 μm and 70 μm, preferably between 7 μm and 35 μm.

The mesh size and the bar width of the layer (L4-g) can be measured using a digital microscope according to any suitable techniques.

The compound (M3) is typically selected from the group consisting of:

(a) Rh, Ir, Ru, Ti, Re, Os, Cd, TI, Pb, Bi, In, Sb, Al, Ti, Cu, Ni, Pd, V, Fe, Cr, Mn, Co, Zn, Mo, W, Ag, Au, Pt, Ir, Ru, Pd, Sn, Ge, Ga, alloys thereof and derivatives thereof, and

(b) metal oxides selected from the group consisting of:
SiOx, ZnO, In₂O₃, SnO₂ and mixtures thereof, wherein x is comprised between 0.5 and 2,
impurity-doped metal oxides selected from the group consisting of ZnO, In₂O₃, SnO₂, CdO and mixtures thereof such as Sn-doped metal oxides selected from the group consisting of ZnO, In₂O₃, SnO₂, CdO and mixtures thereof and Al-doped metal oxides selected from the group consisting of ZnO, In₂O₃, SnO₂, CdO and mixtures thereof, and
Zn₂SnO₄, ZnSnO₃, Zn₂In₂O₅, Zn₃In₂O₆, In₂SnO₄, CdSnO₃ and mixtures thereof.

According to a first variant of the second or third embodiment of the invention, the layer (L4) is typically applied either onto the layer (L2) or onto the layer (L3), if any, by printing techniques, preferably by screen, gravure, flexo or ink-jet printing techniques, more preferably by ink-jet printing techniques.

According to a second variant of the second or third embodiment of the invention, the layer (L4) is typically applied either onto the layer (L2) or onto the layer (L3), if any, by assembling the layer (L4) onto said layer (L2) or said layer (L3).

The layer (L4) may be supported onto a layer consisting of a composition [composition (C1)] comprising, preferably consisting of, at least one thermoplastic polymer [polymer (T1)].

According to a fourth embodiment of the invention, the front-sheet electrode of the display device of the invention is an assembly comprising one or more multilayer assemblies further comprising one or more layers consisting of a compound selected from the group consisting of desiccants and oxygen scavengers.

Non-limitative examples of suitable desiccants include, notably, boron oxide, barium oxide, calcium oxide and zeolites.

Should the disclosure of any patents, patent applications, and publications which are incorporated herein by reference conflict with the description of the present application to the extent that it may render a term unclear, the present description shall take precedence.

1. A process for the manufacture of a display device, said process comprising:
interposing between a the front-sheet electrode and a the back sheet electrode one or more layers consisting of at least one organic semiconductor material, wherein said front-sheet electrode is an assembly comprising one or more multilayer assemblies obtainable by:
treating at least one surface of a layer (L1) with a radio-frequency glow discharge process in the presence of an etching gas medium, wherein layer (L1) consists of a composition (C1) comprising at least one thermoplastic polymer (T1) and wherein layer (L1) has two opposite surfaces;
applying by electroless deposition a layer (L2) consisting of at least one metal compound (M1) onto each treated surface of layer (L1).

2. The process according to claim 1, wherein the front-sheet electrode is optically transparent.

3. The process according to claim 1, wherein the polymer is selected from the group consisting of:
fluoropolymers comprising recurring units derived from at least one fluorinated monomer,
polyesters,
polyolefins,
substituted polyolefins,
polyethersulfones,
polycarbonates,
polyacrylates, and
polyimides.

4. The process according to claim 1, wherein the etching gas medium is selected from the group consisting of air, N₂, NH₃, CH₄, CO₂, He, O₂, H₂ and mixtures thereof.

5. The process according to claim 4, wherein, the etching gas medium comprises N₂ and/or NH₃ and, optionally, H₂.

6. The process according to claim 1, said process further comprising applying by electro-deposition a layer (L3) consisting of at least one metal compound (M2) onto layer (L2), said metal compound (M2) being equal to or different from metal compound (M1).

7. The process according to claim 1, said process further comprising applying a patterned layer (L4) consisting of at least one metal compound (M3) onto layer (L2), said metal compound (M3) being equal to or different from metal compound (M1).

8. The process according to claim 6, said process further comprising applying a patterned layer (L4) consisting of at least one metal compound (M3) onto layer (L3), said metal compound (M3) being equal to or different from metal compound (M1) and metal compound (M2).

9. A display device comprising:
a front-sheet electrode,
a back-sheet electrode, and
directly adhered to the inner surface of the front-sheet electrode and to the inner surface of the back-sheet electrode, one or more layers consisting of at least one organic semiconductor material,
wherein the front-sheet electrode is an assembly comprising one or more multilayer assemblies comprising the following layers:
at least one layer (L1) consisting of a composition (C1) comprising at least one thermoplastic polymer (T1), said layer (L1) layer having two opposite surfaces, wherein at least one surface comprises one or more grafted functional groups [surface (L1-f)], and
directly adhered to the surface (L1-f) of the layer (L1), a layer (L2) consisting of at least one metal compound (M1).

10. The display device according to claim 9, wherein surface (L1-f) comprises one or more grafted functional groups selected from the group consisting of amine groups (—NH₂), imine groups (—CH═NH), nitrile groups (—CN) and amide groups (—CONH₂).

11. The display device according to claim 9, wherein the front-sheet electrode is an assembly comprising one or more multilayer assemblies further comprising, directly adhered to layer (L2), a layer (L3) consisting of at least one metal compound (M2), said metal compound (M2) being equal to or different from the metal compound (M1).

12. The display device according to claim 9, wherein the front-sheet electrode is an assembly comprising one or more multilayer assemblies further comprising, directly adhered to layer (L2), a patterned layer (L4) consisting of at least one metal compound (M3), said metal compound (M3) being equal to or different from metal compound (M1).

13. The display device according to claim 9, wherein the front-sheet electrode is an assembly comprising one or more multilayer assemblies further comprising:
directly adhered to layer (L2), a layer (L3) consisting of at least one metal compound (M2), said metal compound (M2) being equal to or different from metal compound (M1), and
directly adhered to the layer (L3), a patterned layer (L4) consisting of at least one metal compound (M3), said metal compound (M3) being equal to or different from metal compound (M1) and metal compound (M2).

14. The display device according to claim 9, wherein the at least one layer (L1) of the front-sheet electrode is the outer layer of the display device.

15. The display device according to claim 9, wherein layer (L2) has a thickness of between 0.05 μm and 5 μm.

16. The display device according to claim 15, wherein layer (L2) has a thickness of between 0.5 μm and 1.5 μm.
